(19) United States
(12) Patent Application Publication
(10) Pub. No.: US 2012/0021600 A1
(43) Pub. Date: Jan. 26, 2012

(54) METHOD OF FABRICATING FILM CIRCUIT SUBSTRATE AND METHOD OF FABRICATING CHIP PACKAGE INCLUDING THE SAME

(75) Inventors: Sang-Uk Han, Hwaseong-si (KR); Dae-Woo Son, Cheonan-si (KR); Kwan-Jai Lee, Yongin-si (KR); Ye-Chung Chung, Hwaseong-si (KR); Jeong-Kyu Ha, Yongin-si (KR); Yun-Young Kim, Seoul (KR)

(73) Assignee: Samsung Electronics Co., Ltd., Suwon-si (KR)

(21) Appl. No.: 13/184,810

(22) Filed: Jul. 18, 2011

(30) Foreign Application Priority Data
Jul. 20, 2010 (KR) 10-2010-0070077

(51) Int. Cl. H01L 21/283

(52) U.S. Cl. 438/618; 257/E21.159

(57) ABSTRACT

A method of fabricating a film circuit substrate and a method of fabricating a chip package. The method of fabricating a film circuit substrate can include providing a base film including a chip packaging area to package a chip and a separation area to separate the two chip packaging areas from each other, the separation area including a cut area and an uncut area; forming a reserve interconnection pattern having a first height on the base film; and forming an interconnection pattern having a second height that is lower than the first height on the out area by selectively etching the reserve interconnection pattern of the cut area.

### CROSS-REFERENCE TO

This application is based on and claims priority from Korean Patent Application No. 10-2010-0070077, filed on Jul. 20, 2010 in the Korean Intellectual Property Office, the disclosure of which is incorporated herein in its entirety by reference.

### BACKGROUND OF THE INVENTION

1. Field of the Invention

The present inventive concept relates to a method of fabricating a film circuit substrate and a method of fabricating a chip package including the same, and more particularly to a method of fabricating a film circuit substrate and a method of fabricating a chip package including the same, in which heights of a cut area and an uncut area of a wire pattern differ from each other.

2. Description of the Related Art

Various types of semiconductor packages have been presented, and among them, a TAP (Tape Automated Bonding) technology which specially uses an inner lead bonding (ILB) technology has been spotlighted.

The TAB technology is a technology that continuously fabricates packages in a reel-to-reel manner, and the package fabricated by this technology is typically called a TAB package. The TAB package may include a COB (Chip On Board) package and a TCP (Tape Carrier Package).

The TAB package, which is a package suitable to processes for thin film, fine pitch, and the like, was initially used in internal connection, timepiece, calculator, and the like, and at present, it has been widely used as a driver IC for a liquid crystal display. The TAB package which is used as the driver IC for a liquid crystal display is called a DDI (Display Driver IC). Also, the TAB package has now been used in an MPU (Micro-Processor Unit) for a PC.

As a device becomes increasingly fine and thin, demand for a fine-pitch TAB package is increasing. However, at present, such a fine-pitch TAB package has a problem that due to the fine and thin device, a routing space for interconnection patterns is gradually reduced. Further, with the recent increasing tendency of the number of channels, the number of interconnection patterns formed in the package is also increased, and this may cause a short-circuit phenomenon to occur between adjacent interconnection patterns due to metallic particles produced during cutting of the interconnection patterns. Accordingly, the inferiority rate of the device may increase,

### SUMMARY OF THE INVENTION

Accordingly, the present inventive concept can solve the above-mentioned problems occurring in the conventional art, and can provide a method of fabricating a film circuit substrate that can improve the reliability of a chip package.

to the present inventive concept also provides a method of fabricating a chip package with improved reliability.

Additional advantages, utilities and features of the inventive concept will be set forth in part in the description which follows and in part will become apparent to those having ordinary skill in the art upon examination of the following or may be learned from practice of the inventive concept.

Embodiments of the inventive concept provide a method of fabricating a film circuit substrate, which includes providing a base film including a chip packaging area to package a chip and a separation area to separate two chip packaging areas from each other, the separation area including a cut area and an uncut area; forming a reserve interconnection pattern having a first height on the base film; and forming an interconnection pattern having a second height that is lower than the first height on the cut area by selectively etching the reserve interconnection pattern of the cut area.

Embodiments of the inventive concept also provide a method of fabricating a film circuit substrate, which includes providing a base film including a chip packaging area to package a chip and a separation area to separate two chip packaging areas from each other, the separation area including a cut area and an uncut area; forming a seed pattern having a first height on the base film; and forming an interconnection pattern having a second height that is higher than the first height on the uncut area of the seed pattern by selectively depositing a conductive material on the uncut area.

Embodiments of the inventive concept also provide a method of fabricating a chip package, which includes providing a film circuit substrate including a base film having a chip packaging area to package a chip and a separation area to separate the two chip packaging areas from each other and an interconnection pattern formed on the base film, wherein the separation area includes a cut area and an uncut area, and the interconnection pattern has a first height on the cut area and has a second height that is higher than the first height on the uncut area; packaging the chip on the chip packaging area; and cutting the interconnection pattern and the base pattern of the cut area.

More details of other exemplary embodiments are included in the following description and drawings.

Embodiments of the inventive concept also provide a method of fabricating a film circuit substrate, comprising: forming a reserve interconnection pattern having a first height on a base film including chip packaging areas to package a chip and a separation area to separate each chip packaging area from another, the separation area including a cut area and an uncut area; and selectively etching the reserve interconnection pattern at the cut area to form an interconnection pattern.

In an embodiment, the selective etching the reserve interconnection pattern may include: forming a mask on the uncut area of the reserve interconnection pattern; and etching the reserve interconnection pattern to form an interconnection pattern having a second height on the cut area lower than the first height, and removing the mask.

Embodiments of the inventive concept also provide a method of fabricating a file circuit substrate, comprising: providing chip packaging areas and separation areas on a base film, the separation areas including an area to be cut and an uncut area; and forming an interconnection pattern on the base film and having a first height at the uncut area and a second height lower than the first height at the area to be cut.

In an embodiment, the forming of the interconnection pattern may include: forming a reserve interconnection pattern of the first height; forming a mask pattern along the reserve interconnection pattern at the uncut areas; and etching the reserve interconnection pattern such that the unmasked areas become etched to the second height.

In an embodiment, the forming of the interconnection pattern may include: forming a seed pattern of the second height; forming a mask pattern over the seed pattern at the areas to be cut; selectively depositing a conductive material on the uncut areas of the seed pattern to the first height; and removing the mask pattern from the areas to be cut.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIGS. 1 to 3 are cross-sectional views of intermediate structures illustrating a method of fabricating a film circuit substrate according to an embodiment of the present inventive concept;

FIG. 4 is a cross-sectional view taken along a line I-I′ and a line II-II′ of FIG. 3 illustrating height change of an interconnection pattern of FIG. 3;

FIG. 5 is an exemplary plan view of a film circuit substrate fabricated by a method of fabricating a film circuit substrate according to an embodiment of the present invention; and

FIGS. 6 to 9 are perspective views of intermediate structures illustrating a method of fabricating a film circuit substrate according to an embodiment of the present inventive concept.

### DETAILED DESCRIPTION OF THE PREFERRED EMBODIMENTS

Hereinafter, preferred embodiments of the present inventive concept will be described in detail with reference to the accompanying drawings. The aspects and features of the present inventive concept and methods of achieving the features and utilities will be apparent by referring to the embodiments to be described in detail with reference to the accompanying drawings. However, the present inventive concept is not limited to the embodiments disclosed hereinafter, but can be implemented in diverse forms. The matters defined in the description, such as the detailed construction and elements, are nothing but specific details provided to assist those of ordinary skill in the art in a comprehensive understanding of the inventive concept, and the present inventive concept is only defined within the scope of the appended claims. In the drawings, sizes and relative sizes of layers and areas may be exaggerated for clarity in explanation.

In the entire description of the present inventive concept, the same drawing reference numerals are used for the same elements across various figures. Also, the term “and/or” includes the respective described items and combinations thereof.

In the following description of the present inventive concept, the terms used are for explaining embodiments of the present inventive concept, but do not limit the scope of the present inventive concept. In the description, a singular expression may include a plural expression unless specially described. The term “comprises” and/or “composed of” used in the description means that one or more other components, steps, operation and/or existence or addition of elements are not excluded in addition to the described components, steps, operation and/or elements.

Although the terms “first, second, and so forth” are used to describe diverse elements, components and/or sections, such elements, components and/or sections are not limited by the terms. The terms are used only to discriminate an element, component, or section from other elements, components, or sections. Accordingly, in the following description, a first element, first component, or first section may be different from or may be identical to a second element, second component, or second section.

In the following description of the present inventive concept, embodiments of the present inventive concept will be described with reference to plane views and sectional views which are ideal schematic views. The form of exemplary views may be modified due to the manufacturing techniques and/or allowable errors. Accordingly, the embodiments of the present inventive concept are not limited to their specified form as illustrated, but include changes in form being produced according to manufacturing processes. Accordingly, areas exemplified in the drawings have rough properties, and the shapes of areas in the drawings are to exemplify specified forms of areas of elements, but do not limit the scope of the present inventive concept.

Unless specially defined, all terms (including technical and scientific terms) used in the description could be used as meanings commonly understood by those of ordinary skilled in the art to which the present inventive concept belongs. In addition, terms that are generally used but are not defined in the dictionary are not interpreted ideally or excessively unless they have been clearly and specially defined.

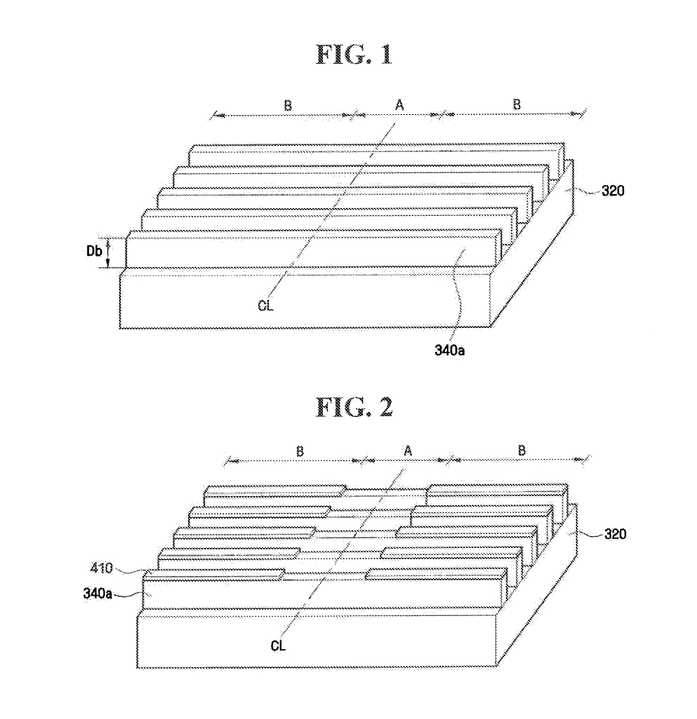

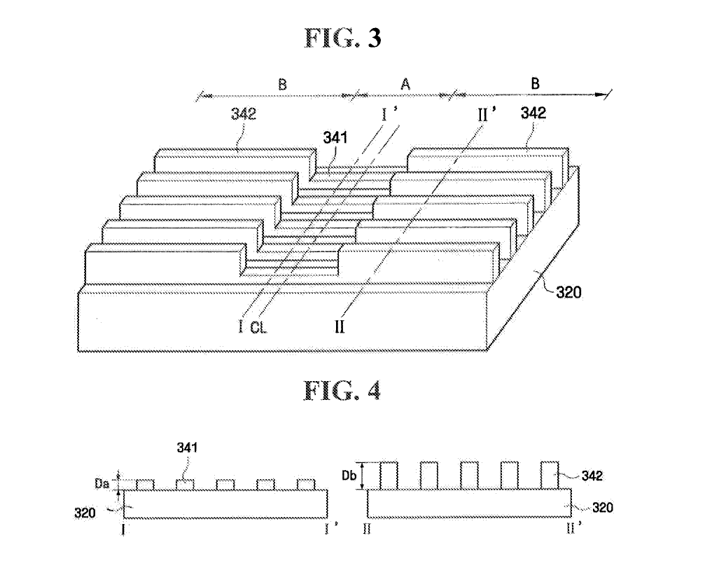

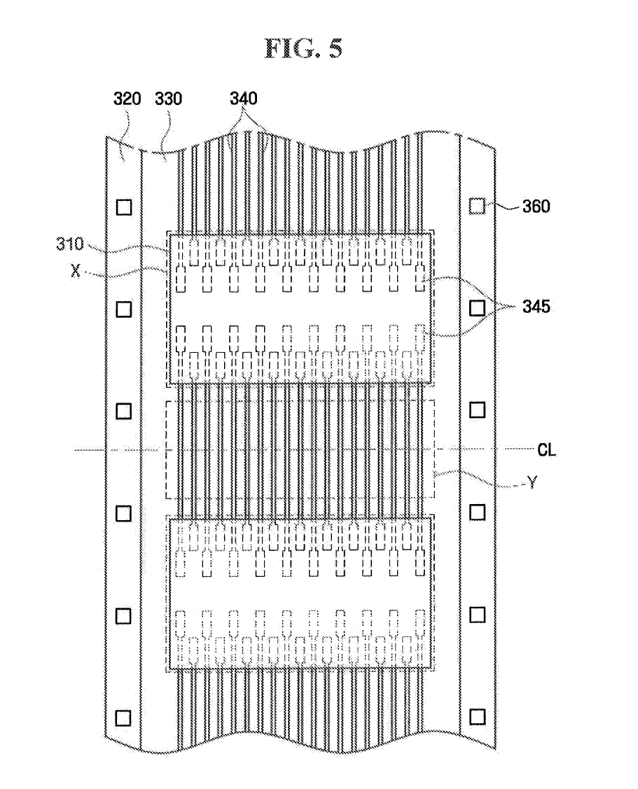

Hereinafter, with reference to FIGS. 1 to 4, a method of fabricating a film circuit substrate according to an embodiment of the present inventive concept will be described. FIGS. 1 to 3 are cross-sectional views of intermediate structures illustrating a method of fabricating a film circuit substrate according to an embodiment of the present inventive concept, and FIG. 4 is a cross-sectional view taken along a line I-I′ and a line II-II′ of FIG. 3 illustrating height change of an interconnection pattern of FIG. 3.

First, referring to FIG. 1, a base film 320 is provided, and a reserve interconnection pattern 340a having a first height Db is formed on the base film 320.

More specifically, the base film 320 includes a chip packaging area (not illustrated) to package a chip (not illustrated) and a separation area (not illustrated) to separate two adjacent chip packaging areas from each other, and the separation area includes a cut area A and an uncut area B.

The cut area A may mean an area that includes a cut line CL to separate two adjacent chip packaging areas from each other. That is, by cutting the film circuit substrate along the cut line CL, the film circuit substrate can be separated in the unit of a chip packaging area. In other words, the cut line CL that is cut by a cutting device during a cutting process and a partial area that is adjacent to the cut line may be defined as the cut area A, and the area except for the cut area A may be defined as the uncut area B.

The base film 320 may be formed of an insulating material, for example, polyimide resin, but is not limited thereto.

Also, as illustrated in FIG. 1, the reserve interconnection pattern 340a having the first height Db is formed on the base film 320 that includes the cut area A and the uncut area B.

The reserve interconnection pattern 340a may be formed to extend in a first direction from a cut line through a chip packaging area or to extend through two adjacent chip packaging areas. In some other embodiments, the reserve interconnection pattern 340a may be formed to extend through two or more chip packaging areas. A part that corresponds to the cut area A on the reserve interconnection pattern 340a extending through two or more chip packaging areas may include the cut line CL cut by the cutting device. In this case, a part of the reserve interconnection pattern 340a on the cut area A can be removed before the cutting process. Accordingly, the amount of contact between the cutting device and the interconnection pattern during the cutting process is minimized, and thus device inferiority due to the occurrence of particles during the cutting process is reduced. The details thereof will be described later.

The forming of the reserve interconnection pattern 340a may include performing a patterning process on the base film 320 using a conductive material. For example, the conductive material may include a metallic material such as copper or the like.

Then, as illustrated in FIG. 2, a first mask pattern 410 to expose the cut area A may be formed on the reserve interconnection pattern 340a.

More specifically, the first mask pattern 410 may be formed on the reserve interconnection pattern 340a with the cut area A including the cut line CL remaining exposed. Unlike the first mask pattern 410 as illustrated in the drawing, the first mask pattern 410 may be formed on not only the reserve interconnection pattern 340a but also on the base film 320 except for the cut area A. In other words, the first mask pattern 410 may be formed so that it exposes the base film 320 and the reserve interconnection pattern 340a at the cut area A, but covers the base film 320 and the reserve interconnection pattern 340a at the uncut area B. That is, the first mask pattern 410 can be formed so that the reserve interconnection pattern 340a at the cut area A is exposed, and a part of the reserve interconnection pattern 340a at the cut area A is then removed in the following etching process.

Then, as illustrated in FIG. 3, by selectively etching an area of the reserve interconnection pattern 340a that corresponds to the cut area A while the mask pattern 410 remains, the interconnection pattern having the second height Da lower than the first height Db is formed at the cut area A.

More specifically, by performing an etching process with respect to the reserve interconnection pattern 340a on which the first mask pattern 410 is formed, a part of the reserve interconnection pattern 340a at the cut area A can be removed. Here, the removing of the part of the reserve interconnection pattern 340a results in lowering of the height of the partial area of the reserve interconnection pattern 340a from the first height Db to the second height Da using an etching process. Accordingly, the interconnection patterns 341 and 342 are formed with the first height Db at the uncut area B, and with the second height Da that is lower than the first height Db at the cut area A, respectively. At this time, an etching process may be performed by dry etching, such as an etch-back process. However, the etching process is not limited thereto, and may be performed by wet etching if necessary.

As illustrated in FIG. 4, the interconnection patterns 341 and 342 may be formed to have different heights at the cut area A and at the uncut area B, and particularly the interconnection pattern 341 at the cut area A may have a height that is lower than the height of the interconnection pattern 342 at the uncut area B. As the interconnection pattern 341 at the cut area A that includes the cut line CL has a lower height, the thickness of the interconnection pattern 341 and the base film 320 of the film circuit substrate, which are cut along the out line CL, is reduced. As illustrated in the drawing, the height Da of the interconnection pattern 341 at the cut area A is lower than the height Db of the interconnection pattern 342 at the uncut area B.

From a different viewpoint, the interconnection patterns 341 and 342 have a first vertical cut surface of a first area at the cut area A and a second vertical cut surface of a second area at the uncut area B, and the first area is smaller than the second area. Here, the vertical cut surfaces may refer to surfaces obtained by cutting the interconnection patterns 341 and 342 in a vertical direction with respect to the surface of the base film 320. In this case, the direction that is vertical to the surface of the base film 320 refers to the substantially vertical direction, but is not limited to the direction that is strictly at an angle of 90° with respect to the surface of the base file 320. Further, the vertical cut surfaces may refer to surfaces obtained by cutting the interconnection patterns 341 and 342 in a process of cutting the film circuit substrate to be described later.

Further, the mask pattern 410 may be removed by the following process.

According to the methods of fabricating the film circuit substrate according to the embodiments of the present inventive concept, by forming the interconnection patterns 341 and 342 so that the thickness, i.e. the height, of the interconnection pattern 341 arranged at the cut area A becomes smaller than the thickness, i.e. the height, of the interconnection pattern 342 arranged at the uncut area B, the cross-sectional area, in which the interconnect pattern 341 is in contact with a cutting tool of the cutting device, can be reduced. Accordingly, metallic particles which are generated while the interconnection pattern 341 is being cut can be reduced, and thus the adjacent interconnections can be prevented from being short-circuited due to such particles. That is, according to the methods of fabricating the film circuit substrate according to the embodiments of the present inventive concept, a film circuit substrate having improved reliability can be fabricated.

Hereinafter, with reference to FIG. 5, a film circuit substrate fabricated by a method of fabricating the film circuit substrate according to another embodiment of the present inventive concept will be described. FIG. 5 is an exemplary plan view of a film circuit substrate fabricated by a method of fabricating a film circuit substrate according to an embodiment of the present inventive concept. For convenience in explanation, the detailed explanation of the constituent elements substantially the same as those as described above will be omitted or simplified.

As described above, the base film 320 includes at least one chip packaging area X on which a chip 310 is packaged, and at least one separation area Y that separates two adjacent chip packaging areas X from each other, and as illustrated in FIGS. 1 to 3, the separation area Y includes a cut area (see “A” in FIG. 1) and an uncut area (see “B” in FIG. 1). In this case, the cut area includes a cut line CL, and the cut line CL may refer to the line that is cut when the film circuit substrate is separated in the unit of a chip packaging area in the process of cutting the film circuit substrate.

Although not illustrated in the drawing, a window may be formed in a portion where a semiconductor chip is packaged in the chip packaging area X of the base film 320. In this case, the film circuit substrate may be called a TCP (Tape Carrier Package). Also, as illustrated in the drawing, the window may not be formed in the chip packaging area X of the base film 320. In this case, the film circuit substrate may be called a COF (Chip On Film). The method of fabricating the film circuit substrate according to embodiments of the present inventive concept may include a method of fabricating a TCP or COF.

The base film 320 may be formed of, for example, an insulating material such as polyimide resin, but is not limited thereto. Further, on both ends of the base film 320, a transmission hole 360 may be formed along the length direction.

The interconnection pattern 340 is formed on the base film 320. The interconnection pattern 340 may be formed of a conductive material. For example, the interconnection pattern 340 may be formed of a material such as copper or the like.

Further, on the base film 320 on which the interconnection pattern 340 is formed, a protective layer 330 may be formed. For example, the protective layer 330 may be entirely formed on the base film 320 so that the interconnection pattern 340 is not exposed to the outside. However, leads 345 connected to the semiconductor chip may not be covered by the protective layer 330. In other words, the interconnection pattern 340 is covered by the protective layer 330 and is formed to extend to the chip packaging area X and the separation area Y, while the leads 345 connected to the interconnection pattern 340 are exposed by the protective layer 330 and may be formed to project to the inside of the chip packaging area.

As described above, in forming the interconnection patterns that pass through the cut area A and the uncut area B included in the separation area Y of the base film 320, the height of the interconnection pattern 341 arranged at the cut area A is set to be lower than the height of the interconnection pattern arranged at the uncut area B, and thus the area, in which a cutting device, for example, a cutting saw or the like, is in contact with the interconnect pattern 341 in the following cutting process, can be reduced. Accordingly, generation of particles due to the contact between the cutting device and the interconnection pattern 341 can be reduced, and thus the device inferiority caused by the particles can be reduced.

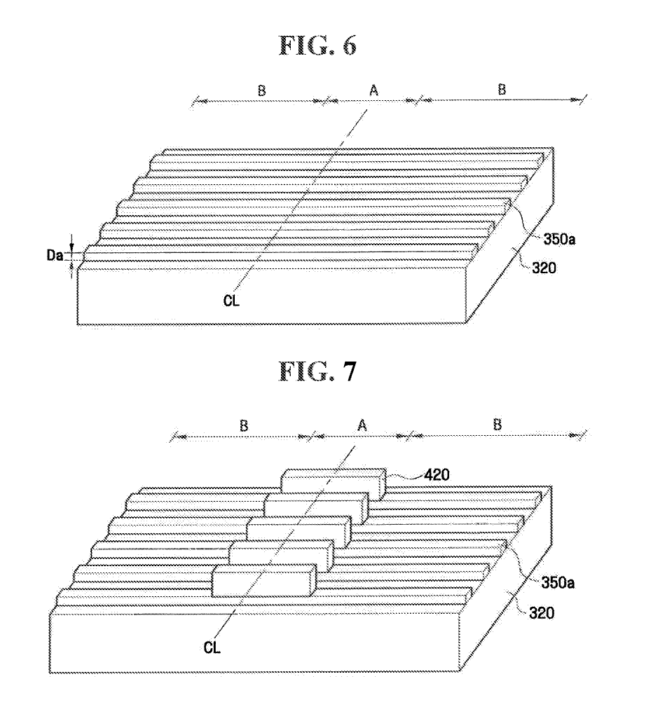

Hereinafter, with reference to FIGS. 6 to 9, a method of fabricating a film circuit substrate according to another embodiment of the present inventive concept will be described. FIGS. 6 to 9 are perspective views of intermediate structures illustrating a method of fabricating a film circuit substrate according to an embodiment of the present inventive concept.

A method of fabricating the film circuit substrate according to another embodiment of the present inventive concept may be distinguished from the method according to the above-described embodiments on the point that a plating process is adopted in forming the interconnection patterns. For convenience in explanation, the detailed explanation of the constituent elements substantially the same as those as described above will be omitted or simplified.

Referring to FIG. 6, a seed pattern 350a having a first height Da is formed on the base film 320.

More specifically, the base film 320 includes a chip packaging area (see “X” in FIG. 5) to package a chip (see “310” in FIG. 5) and a separation area (see “Y” in FIG. 5) to separate two adjacent chip packaging areas from each other, and the separation area Y includes a cut area A and an uncut area B. The cut area A includes a cut line CL, and by cutting the film circuit substrate along the cut line CL, the film circuit substrate can be separated in the unit of a chip packaging area.

As illustrated in FIG. 6, the seed pattern 350a having the first height Da is formed on the base film 320 that includes the cut area A and the uncut area B. At this time, the seed pattern 350a may be formed to extend in the first direction, and may be formed to extend through two adjacent chip packaging areas X. Also, from a different viewpoint, the seed pattern 350a may be formed along a line in which an interconnection pattern 340 is formed.

The forming of the seed pattern 350a may include performing a patterning process on the base film 320 using a conductive material. For example, the conductive material may include a metallic material such as copper or the like.

Then, referring to FIG. 7, a mask pattern 420 that covers the cut area A of the seed pattern 350a is formed.

More specifically, the mask pattern 420 is formed on the seed pattern 350a so that the mask pattern covers the cut area A including the cut line CL. Also, in some other embodiments, unlike those as illustrated in the drawings, the mask pattern 420 may be formed on not only the seed pattern 350a that corresponds to the cut area A, but also the base film 320 that corresponds to the cut area A. Consequently, it is sufficient if the seed pattern 350a that corresponds to the uncut area B is exposed by the mask pattern 420.

For example, the mask pattern 420 may be a photoresist pattern, and may be formed by a photo etching process. However, the mask pattern 420 is not limited to such a material or process.

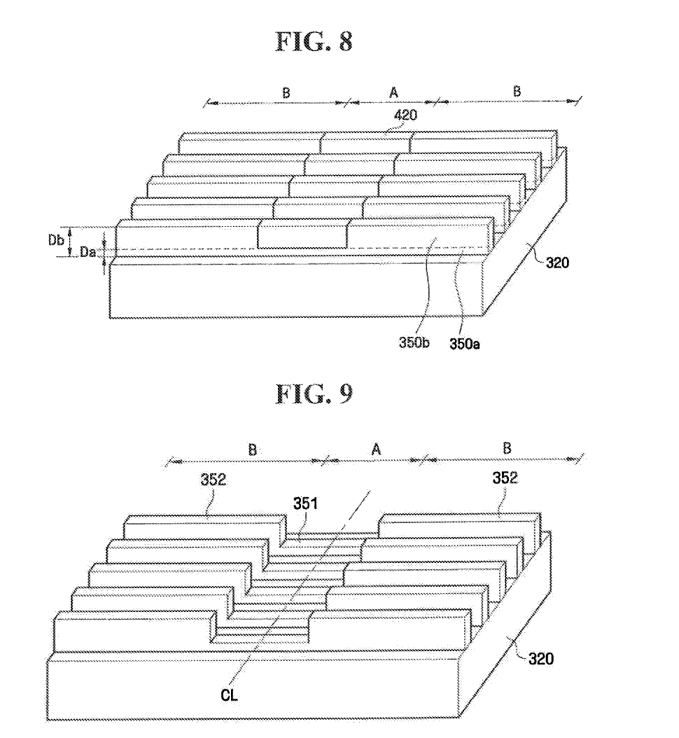

Then, referring to FIG. 8, interconnection patterns 350a and 350b having a second height Db that is higher than the first height Da are formed by selectively depositing a conductive material on the uncut area B of the seed pattern 350a.

More specifically, by performing a plating process on the seed pattern 350a in a state where the mask pattern 420 that covers the cut area A is formed, the interconnection patterns 350a and 350b can be formed on the uncut area B with the second height Db. As illustrated in FIG. 8, the conductive material is not deposited on the seed pattern 350a of the cut area A that is intercepted by the mask pattern 420. By contrast, by selectively depositing the conductive material 350b on the seed pattern 350a of the uncut area B that is exposed by the mask pattern 420, the interconnection patterns 350a and 350b can be formed with the second height Db.

Although only the cut area A and uncut area B of the separation area Y are partially illustrated in the drawings, the conductive material 350b may also be formed on the seed pattern 350a that is exposed by the mask pattern 420 in addition to the separation area Y.

Next, while referring to FIG. 9, an exemplary embodiment of how the mask pattern 420 is removed will be described.

As illustrated in the drawing, as the mask pattern 420 is removed, the interconnection patterns 350a and 350b, which have the first height Da on the cut area A and the second height Db that is higher than the first height Da on the uncut area B, may be formed. As described above, by forming the interconnection pattern 350a and 350b having the height on the cut area A that is relatively lower than the height on the uncut area B, a relatively small cut surface is provided.

In other words, as described above with reference to FIG. 3, the interconnection patterns 341 and 342 have a first vertical cut surface of a first area on the out area A and a second vertical cut surface of a second area on the uncut area B, and the first area of the first vertical cut surface is smaller than the second area of the second vertical cut surface. Accordingly, the possibility of generating particles is lowered when the film circuit substrate is being cut along the cut line CL rather than when the uncut area B having a relatively large cut surface is cut. Accordingly, the possibility that a short-circuit phenomenon between adjacent interconnections occurs due to particles released during cutting of the substrate is reduced, and thus an inferiority rate of the resulting device is also reduced.

Referring again to FIG. 5, according to a method of fabricating the film circuit substrate according to an embodiment of the present inventive concept, the chip 310 is packaged on the chip packaging area X of the film circuit substrate fabricated according to the embodiments of the present inventive concept, and the interconnection pattern 350a and the base pattern 320 on the cut area A are cut. For convenience in explanation, the detailed explanation of the contents substantially the same as those in the method of fabricating the film circuit substrate according to the embodiments of the present invention will be omitted.

More specifically, the cutting of the interconnection pattern 350a and the base pattern 320 of the cut area A may include a process of separating two adjacent chip packaging areas X from each other along the cut line CL defined in the cut area A using the cutting device.

As described above, since the height of the interconnection pattern 350a on the cut area A is lower than the height of the interconnection pattern 350a and 350b in the uncut area B, the cutting device can cut the film circuit substrate by penetrating a relatively small cut surface. Accordingly, the possibility of generating particles during the cutting process is lowered, and thus a device having an improved reliability can be fabricated.

Although preferred embodiments of the present inventive concept have been described for illustrative purposes, those skilled in the art will appreciate that various modifications, additions and substitutions are possible, without departing from the scope and spirit of the general inventive concept as disclosed in the accompanying claims.

What is claimed is:

1. A method of fabricating a film circuit substrate, comprising:
providing a base film including chip packaging areas to package a chip and a separation area to separate two chip packaging areas from each other, the separation area including a cut area and an uncut area;
forming a reserve interconnection pattern having a first height on the base film; and
forming an interconnection pattern having a second height that is lower than the first height at the cut area by selectively etching the reserve interconnection pattern of the cut area.

2. The method of claim 1, wherein the selective etching the reserve interconnection pattern comprises:
forming a mask pattern to expose the cut area on the reserve interconnection pattern; and
forming the interconnection pattern so that the interconnection pattern has the second height at the cut area by performing an etching process on the reserve interconnection pattern formed the mask pattern.

3. The method of claim 1, wherein the cut area includes a cut line to separate the two chip packaging areas from each other.

4. The method of claim 1, wherein the forming the reserve interconnection pattern includes performing a patterning process on the base film using a conductive material.

5. The method of claim 4, wherein the conductive material includes copper.

6. The method of claim 1, wherein, in forming the interconnection pattern, the interconnection pattern has a first vertical cut surface of a first area on the cut area and a second vertical cut surface of a second area on the uncut area; and
the first area is smaller than the second area.

7. A method of fabricating a film circuit substrate, comprising:
providing a base film including chip packaging areas to package a chip and a separation area to separate two chip packaging areas from each other, the separation area including a cut area and an uncut area;
forming a seed pattern having a first height on the base film; and
forming an interconnection pattern having a second height that is higher than the first height at the uncut area of the seed pattern by selectively depositing a conductive material on the uncut area.

8. The method of claim 7, wherein the selectively depositing the interconnection pattern comprises:
forming a mask pattern to cover the cut area of the seed pattern; and
forming the interconnection pattern so that the interconnection pattern has the second height on the uncut area by performing a plating process on the seed pattern.

9. The method of claim 7, wherein the cut area is an area that includes a cut line to separate two adjacent chip packaging areas from each other.

10. The method of claim 7, wherein the conductive material includes copper.

11. The method of claim 7, wherein, in forming the interconnection pattern, the interconnection pattern has a first vertical cut surface of a first area on the cut area and a second vertical cut surface of a second area on the uncut area; and
the first area is smaller than the second area.

12. A method of fabricating a file circuit substrate, comprising:
providing chip packaging areas and separation areas on a base film, the separation areas including an area to be cut and an uncut area; and
forming an interconnection pattern on the base film and having a first height at the uncut area and a second height lower than the first height at the area to be cut.

13. The method of claim 12, wherein the forming of the interconnection pattern comprises:
forming a reserve interconnection pattern of the first height;
forming a mask pattern along the reserve interconnection pattern at the uncut areas; and
etching the reserve interconnection pattern such that the unmasked areas become etched to the second height.

14. The method of claim 12, wherein the forming of the interconnection pattern comprises:
forming a seed pattern of the second height;
forming a mask pattern over the seed pattern at the areas to be cut;
selectively depositing a conductive material on the uncut areas of the seed pattern to the first height; and
removing the mask pattern from the areas to be cut.
